(19) United States
(12) Patent Application Publication
(10) Pub. No.: US 2006/0012434 A1
(43) Pub. Date: Jan. 19, 2006

(54) Variable gain amplifier

(75) Inventors: Yoshinori Takahashi, Tokyo (JP); Hisato Ishimoto, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/526,436

(22) PCT Filed: Sep. 19, 2002
(86) PCT No.: PCT/JP02/09639

§ 371 Date: Mar. 3, 2005

(51) Int. Cl. H03G 3/30

(52) U.S. Cl. 330/278

(57) ABSTRACT

A variable gain amplifier includes a plurality of element circuits each having an output current that increases at a constant rate with a change in a variable control voltage, voltages that increase in steps of the change being respectively supplied to the plurality of element circuits as their reference voltages and the control voltage being supplied to each of the plurality of element circuits, multipliers for multiplying the output currents from the plurality of element circuits by one another, and an amplifier for carrying out a variable gain amplification based on an output current from the multipliers. The variable gain amplifier can suppress any change in the characteristics thereof due to temperature compensation of the characteristics and variations in manufacturing of transistors, and carry out a linear gain control operation on the control voltage when the gain is expressed in a logarithm.

### FIELD OF THE INVENTION

The present invention relates to a variable gain amplifier that linearly controls its gain (dB) expressed in a logarithm with respect to a control voltage by exponentially controlling the gain with respect to the control voltage.

### BACKGROUND OF THE INVENTION

FIG. 1 is a circuit diagram showing a prior art variable gain amplifier. In the figure, reference numeral 1 denotes a variable voltage power supply, reference numeral 2 denotes a common emitter transistor, and reference numeral 3 denotes an amplifier.

Next, the operation of the prior art variable gain amplifier will be explained.

As shown in FIG. 1, when a control voltage V_{BE} generated by the variable voltage power supply I linearly varies, a collector current Ic passing through the common emitter transistor 2 varies according to an exponential function of the control voltage V_{BE}. By supplying the collector current Ic that varies according to this exponential function to the amplifier 3 as a current source, the gain of the amplifier 3 is exponentially controlled with respect to the control voltage V_{BE}.

Thus, the gain (dB) of the amplifier 3 expressed in a logarithm is linearly controlled with respect to the control voltage V_{BE} by exponentially controlling the gain with respect to the control voltage V_{BE}.

A relationship between the collector current Ic and the control voltage V_{BE} is expressed by the following equation (1):
Ic=Is*exp((q/k*T)*V_{BE}) (1)
where Is is a saturated current, q is a charge, k is the Boltzmann's constant, and T is an absolute temperature.

In the prior art variable gain amplifier constructed as mentioned above, the collector current Ic that varies according to the exponential function of the control voltage V_{BE} is dependent upon the absolute temperature T, as can be seen from equation (1), and this characteristics cannot be temperature-compensated with a high degree of precision.

Another problem with the prior art variable gain amplifier is that the slope of the collector current Ic vs. control voltage V_{BE} characteristics curve varies when the saturation-current Is varies due to variations in manufacturing of the transistor 2 in above-mentioned equation (1), and this change in the characteristics due to variations in manufacturing of the transistor 2 cannot be suppressed.

The present invention is made in order to solve the above-mentioned problems, and it is therefore an object of the present invention to provide a variable gain amplifier that linearly controls its gain (dB) expressed in a logarithm with respect to a control voltage by suppressing changes in its characteristics due to temperature compensating of the characteristics and variations in manufacturing of transistors included in the variable gain amplifier, and by exponentially controlling its gain with respect to the control voltage.

### DISCLOSURE OF THE INVENTION

A variable gain amplifier in accordance with an aspect of the present invention described in claim 1 includes a plurality of element circuits each of which has two inputs which are a reference voltage and a control voltage which can vary with respect to the reference voltage, and each of which has an output current that increases at a constant rate with a predetermined change in the control voltage, voltages which increase in steps of the predetermined change in the control voltage being respectively supplied to the plurality of element circuits as their reference voltages and the variable control voltage being supplied to each of the plurality of element circuits, multipliers for multiplying the output currents from the plurality of element circuits by one another, and an amplifier for carrying out a variable gain amplification based on an output current obtained by the multipliers.

The output current output from the multipliers thus exhibits control voltage vs. output current characteristics in which the output current varies with respect to the control voltage according to an exponential function. When the gain is expressed in a logarithm, the variable gain amplifier can carry out linear gain control with respect to the control voltage. Although the control voltage vs. output current characteristics of each of the plurality of element circuits are varied dependently upon temperatures, temperature-dependent changes in the slopes of the control voltage vs. output current characteristics curves of any two adjacent element circuits at a connecting point between them can be compensated and therefore the temperature dependence of the control voltage vs. output current characteristics of the variable gain amplifier can be compensated. In addition, the control voltage vs. output current characteristics can be hardly changed regardless of variations in manufacturing of transistors in the whole of the variable gain amplifier, and any change in the characteristics of the variable gain amplifier due to variations in manufacturing of the transistors can be suppressed.

In the variable gain amplifier in accordance with another aspect of the present invention described in claim 2, each of the plurality of element circuits includes a first transistor to which the control voltage is supplied, a second transistor to which the reference voltage is supplied and which constitutes a differential pair together with the first transistor, and a third transistor to which the reference voltage is supplied and which constitutes a current mirror circuit together with the second transistor, a ratio between the second transistor and the third transistor in size being 1:N−1 when the constant rate at which the output current increases is N−1, the output current being output in common from ends of the first and second transistors and a constant current source that outputs a maximum output current being connected in common to other ends of the first through third transistors.

Therefore, each of the plurality of element circuits can have a simple structure.

In the variable gain amplifier in accordance with a further aspect of the present invention described in claim 3, each of the plurality of element circuits includes a first transistor having an end connected to a constant current source, a second transistor which constitutes a current mirror circuit together with the first transistor, a third transistor which constitutes a current mirror circuit together with the first transistor, the third transistor having an end connected to an output current terminal, a fourth transistor to which the reference voltage is supplied, a fifth transistor to which the control voltage is supplied and which constitutes a differential pair together with the fourth transistor, ends of the fifth and fourth transistors being connected in common to an end of the second transistor, and a transistor circuit network that diverts a part of a current from the output current terminal in proportion to a current flowing through the fifth transistor and that makes the part of the current pass therethrough without making it flow through the third transistor, sizes of the second and third transistors and transistors included in the transistor circuit network being determined so that a ratio between the diverted part of the current and the current flowing through the third transistor is N−1:1 when the diverted part of the current has a maximum value.

Therefore, each of the plurality of element circuits can have a simple structure.

A variable gain amplifier in accordance with another aspect of the present invention described in claim 4 includes a plurality of cascade-connected element circuits each of which has two inputs which are a reference voltage and a control voltage which can vary with respect to the reference voltage, and each of which has an output current that increases at a constant rate with a predetermined change in the control voltage, an input current being supplied to a first-stage one of the plurality of element circuits, voltages which increase in steps of the predetermined change in the control voltage being respectively supplied to the plurality of element circuits as their reference voltages, and the variable control voltage being supplied to each of the plurality of element circuits, and an amplifier for carrying out a variable gain amplification based on an output current from the plurality of element circuits.

The output current output from the plurality of element circuits thus exhibits control voltage vs. output current characteristics in which the output current varies with respect to the control voltage according to an exponential function. When the gain is expressed in a logarithm, the variable gain amplifier can carry out linear gain control with respect to the control voltage. Although the control voltage vs. output current characteristics of each of the plurality of element circuits are varied dependently upon temperatures, temperature-dependent changes in the slopes of the control voltage vs. output current characteristics curves of any two adjacent element circuits at a connecting point between them can be compensated and therefore the temperature dependence of the control voltage vs. output current characteristics of the variable gain amplifier can be compensated. In addition, the control voltage vs. output current characteristics can be hardly changed regardless of variations in manufacturing of transistors in the whole of the variable gain amplifier, and any change in the characteristics of the variable gain amplifier due to variations in manufacturing of the transistors can be suppressed.

In the variable gain amplifier in accordance with another aspect of the present invention described in claim 5, each of the plurality of element circuits includes a first transistor to which the control voltage is supplied, a second transistor to which the reference voltage is supplied and which constitutes a differential pair together with the first transistor, a third transistor to which the reference voltage is supplied and which constitutes a current mirror circuit together with the second transistor, a ratio between the second transistor and the third transistor in size being 1:N−1 when the constant rate at which the output current increases is N−1, a fourth transistor having an end into which an input current flows, a fifth transistor that has an end connected in common to ends of the first through third transistors, and that constitutes a current mirror circuit together with the fourth transistor, and an output current circuit connected in common to other ends of the first and second transistors.

Therefore, each of the plurality of element circuits can have a simple structure.

In the variable gain amplifier in accordance with a further aspect of the present invention described in claim 6, each of the plurality of element circuits includes a first transistor having an end into which an input current flows, a second transistor which constitutes a current mirror circuit together with the first transistor, a third transistor which constitutes a current mirror circuit together with the first transistor, the third transistor having an end-connected to an output current circuit, a fourth transistor to which the reference voltage is supplied, a fifth transistor to which the control voltage is supplied and which constitutes a differential pair together with the fourth transistor, ends of the fifth and fourth transistors being connected in common to an end of the second transistor, and a transistor circuit network that diverts a part of a current from the output current circuit in proportion to a current flowing through the fifth transistor and that makes the part of the current pass therethrough without making it flow through the third transistor, and characterized in that sizes of the second and third transistors and transistors included in the transistor circuit network are determined so that a ratio between the diverted part of the current and the current flowing through the third transistor is N−1:1 when the diverted part of the current has a maximum value.

Therefore, each of the plurality of element circuits can have a simple structure.

A variable gain amplifier in accordance with a still further aspect of the present invention described in claim 7 includes a plurality of cascade-connected element circuits each of which has two inputs which are a reference voltage and a control voltage which can vary with respect to the reference voltage, and each of which has a gain that increases at a constant rate with a predetermined change in the control voltage, an input voltage being supplied to a first-stage one of the plurality of element circuits, voltages which increase in steps of the predetermined change in the control voltage being respectively supplied to the plurality of element circuits as their reference voltages, the variable control voltage being supplied to each of the plurality of element circuits, and an output voltage being generated by a last-stage one of the plurality of element circuits.

Therefore, when the gain is expressed in a logarithm, the variable gain amplifier can carry out linear gain control with respect to the control voltage using the plurality of element circuits. Although the control voltage vs. gain characteristics of each of the plurality of element circuits are varied dependently upon temperatures, temperature-dependent changes in the slopes of the control voltage vs. gain characteristics curves of any two adjacent element circuits at a connecting point between them can be compensated and therefore the temperature dependence of the control voltage vs. gain characteristics of the variable gain amplifier can be compensated. In addition, the control voltage vs. gain characteristics can be hardly changed regardless of variations in manufacturing of transistors in the whole of the variable gain amplifier, and any change in the characteristics of the variable gain amplifier due to variations in manufacturing of the transistors can be suppressed.

In the variable gain amplifier in accordance with another aspect of the present invention described in claim 8, each of the plurality of element circuits includes a first transistor to which the control voltage is supplied, a second transistor to which the reference voltage is supplied and which constitutes a differential pair together with the first transistor, a third transistor to which the reference voltage is supplied and which constitutes a current mirror circuit together with the second transistor, a ratio between the second transistor and the third transistor in size being 1:N−1 when the constant rate at which the gain increases is N−1, a fourth transistor to which an input voltage is supplied, the fourth transistor having an end connected in common to ends of the first through third transistors, and a resistor connected between other ends of the first and second transistors and a power supply, each of the plurality of element circuits generating an output voltage from between the resistor and the other ends of the first and second transistors.

Therefore, each of the plurality of element circuits can have a simple structure.

### BRIEF DESCRIPTION OF THE FIGURES

FIG. 1 is a circuit diagram showing a prior art variable gain amplifier;

FIG. 2 is a block diagram showing an element circuit in accordance with embodiment 1 of the present invention;

FIG. 3 is a characteristics figure showing control voltage vs. output current characteristics of the element circuit;

FIG. 4 is a block diagram showing a variable gain amplifier;

FIG. 5 is a characteristics figure showing control voltage vs. output current characteristics of the variable gain amplifier;

FIG. 6 is a characteristics figure showing temperature dependence of the control voltage vs. output current characteristics of the element circuit;

FIG. 7 is a characteristics figure showing the control voltage vs. output current characteristics of the variable gain amplifier at a high temperature;

FIG. 8 is a characteristics figure showing the control voltage vs. output current characteristics of the variable gain amplifier at a low temperature;

FIG. 9 is a circuit diagram showing the details of an example of an element circuit in accordance with embodiment 2 of the present invention;

FIG. 10 is a circuit diagram showing the details of another example of the element circuit;

FIG. 11 is a circuit diagram showing the details of an example of an element circuit in accordance with embodiment 3 of the present invention;

FIG. 12 is a circuit diagram showing the details of another example of the element circuit;

FIG. 13 is a block diagram showing an element circuit in accordance with embodiment 4 of the present invention;

FIG. 14 is a characteristics figure showing control voltage vs. output current characteristics of the element circuit;

FIG. 15 is a block diagram showing a variable gain amplifier;

FIG. 16 is a characteristics figure showing control voltage vs. output current characteristics of the variable gain amplifier;

FIG. 17 is a circuit diagram showing the details of an example of an element circuit in accordance with embodiment 5 of the present invention;

FIG. 18 is a circuit diagram showing the details of another example of the element circuit;

FIG. 19 is a circuit diagram showing the details of an example of an element circuit in accordance with embodiment 6 of the present invention;

FIG. 20 is a circuit diagram showing the details of another example of the element circuit;

FIG. 21 is a block diagram showing an element circuit in accordance with embodiment 7 of the present invention;

FIG. 22 is a characteristics figure showing control voltage vs. gain characteristics of the element circuit;

FIG. 23 is a block diagram showing a variable gain amplifier;

FIG. 24 is a characteristics figure showing control voltage vs. gain characteristics of the variable gain amplifier; and

FIG. 25 is a circuit diagram showing the details of an example of an element circuit in accordance with embodiment 6 of the present invention.

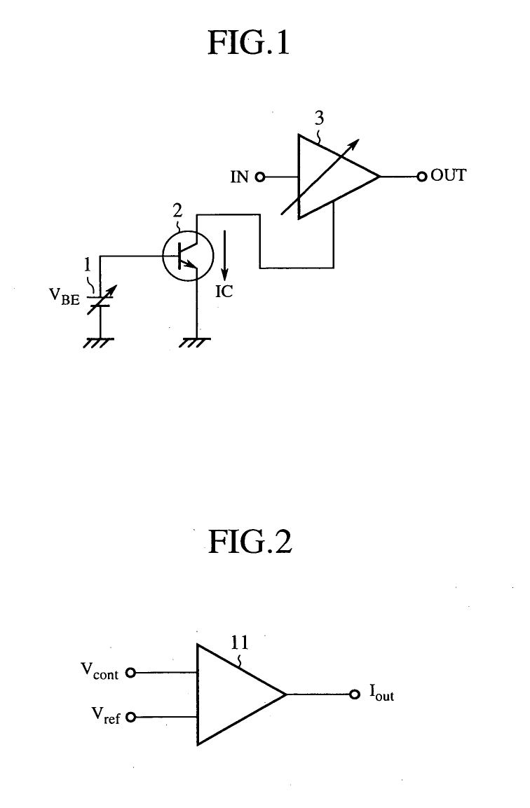

### PREFERRED EMBODIMENTS OF THE INVENTION

Hereafter, in order to explain this invention in greater detail, the preferred embodiments of the present invention will be described with reference to the accompanying drawings. Embodiment 1.

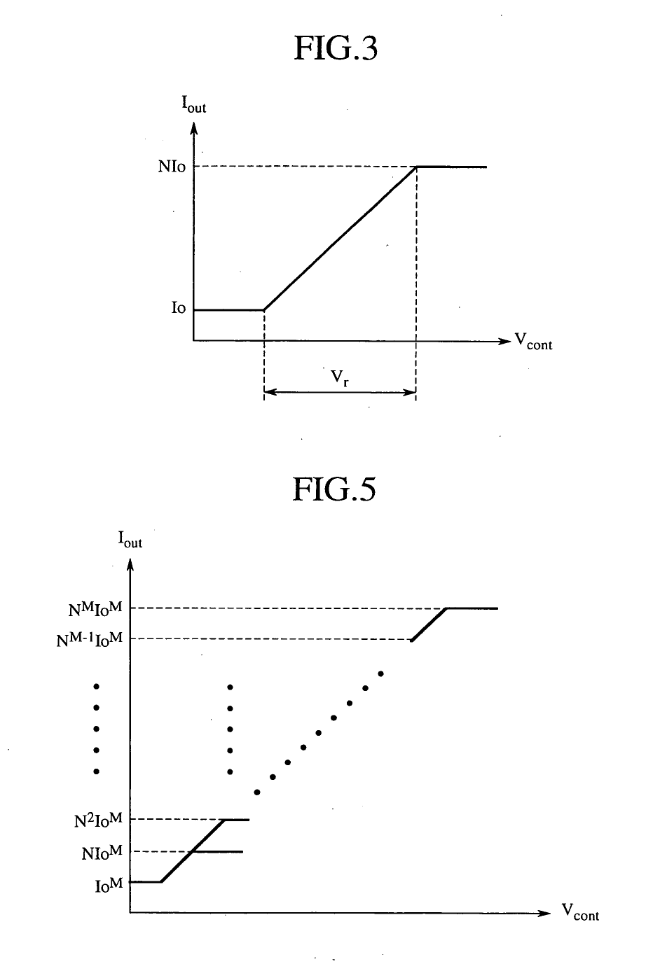

FIG. 2 is a block diagram showing an element circuit in accordance with embodiment 1 of the present invention. In the figure, reference numeral 11 denotes the element circuit. FIG. 3 is a figure showing control voltage vs. output current characteristics of the element circuit.

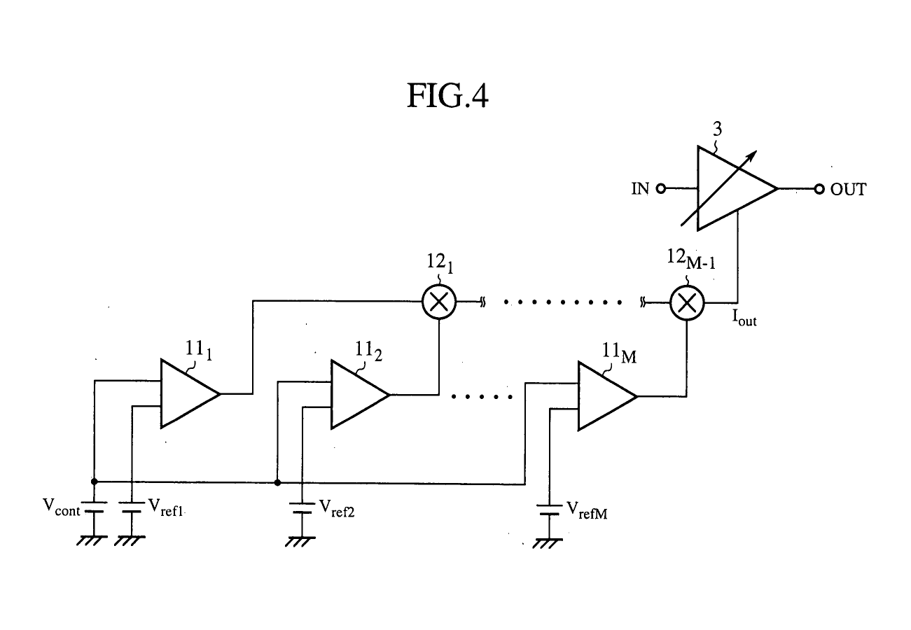

FIG. 4 is a block diagram showing a variable gain amplifier. In the figure, reference numeral 3 denotes an amplifier, reference symbols 11₁ to 11_{M} denote M element circuits (M is an arbitrary natural number), respectively, and reference symbols 12₁ to 12_{M-1} denote M−1 multipliers, respectively. FIG. 5 is a characteristics figure showing control voltage vs. output current characteristics of the variable gain amplifier.

Next, the operation of the variable gain amplifier in accordance with embodiment 1 of the present invention will be explained.

As shown in FIG. 2, the element circuit 11 has signal inputs which are a reference voltage Vref and a control voltage Vcont, and a signal output which is a current Iout. The element circuit 11 has certain control voltage vs. output current characteristics in which the amount of the output current Iout varies from I₀ to N*I₀ (N is an arbitrary number larger than 1) with a predetermined change Vr in the control voltage, that is, the rate of increase in the output current is N−1 when the control voltage Vcont can be varied with respect to the reference voltage Vref, as shown in FIG. 3.

As shown in FIG. 4, M above-mentioned element circuits 11, i.e., the M element circuits 11₁ to 11_{M} are disposed in the variable gain amplifier, and voltages that increase in steps of the predetermined voltage change Vr in the control voltage are respectively supplied to the plurality of element circuits 11₁ to 11_{M} as their reference voltages Vref1 to VrefM. That is, (VrefM)−(VrefM−1)=Vr. The variable control voltage Vcont is supplied in common to the plurality of element circuits 11₁ to 11_{M}.

The plurality of multipliers 12₁ to 12_{M-1} multiply the output currents Iout of the plurality of element circuits 11₁ to 11_{M} by one another to generate an output current Iout, and the variable gain control of the amplifier 3 is carried out based on the output current Iout generated by the plurality of multipliers.

As a result, as shown in FIG. 5, the variable gain amplifier has control voltage vs. output current characteristics in which the amount of the output current Iout varies from I₀^{M}, via N*I₀^{M}, N²*I₀^{M}, . . . , to N^{M}*I₀^{M} and is approximately expressed by an exponential function with respect to the voltage change Vr in the control voltage Vcont. When the gain of the amplifier 3 is expressed in a logarithm, the gain of the amplifier 3 can be linearly controlled with respect to the control voltage Vcont.

Thus, since the variable gain amplifier does not use exponential characteristics of transistors included in the variable gain amplifier, any change in the characteristics of the variable gain amplifier due to variations in manufacturing of the transistors can be suppressed.

By setting the number of element circuits, as stages, included in the variable gain amplifier to an appropriate number and generating the plurality of reference voltages Vrefl to VrefM with a high degree of precision, the slope of the control voltage vs. output current characteristics curve can be hardly changed regardless of variations in manufacturing of the transistors in the whole of the variable gain amplifier, and any change in the characteristics of the variable gain amplifier can be suppressed.

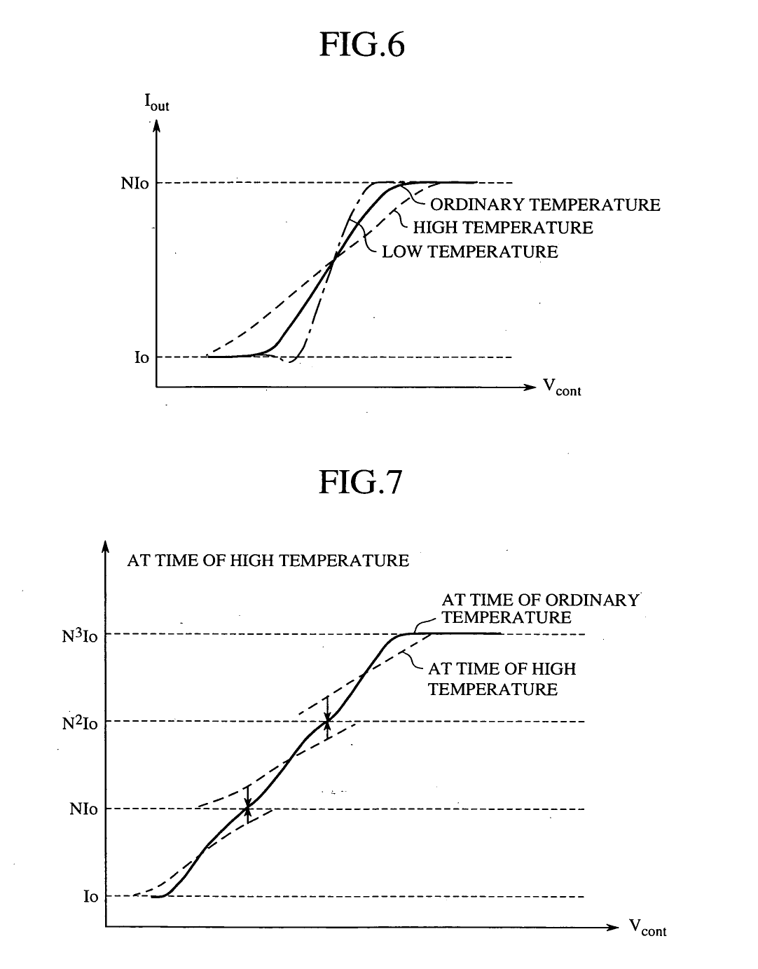

FIG. 6 is a characteristics figure showing temperature dependence of the control voltage vs. output current characteristics of each of the plurality of element circuits. The slope of the control voltage vs. output current characteristics curve of each of the plurality of element circuits decreases with increase in the ambient temperature with respect to ordinary temperatures, and increases with decrease in the ambient temperature with respect to ordinary temperatures.

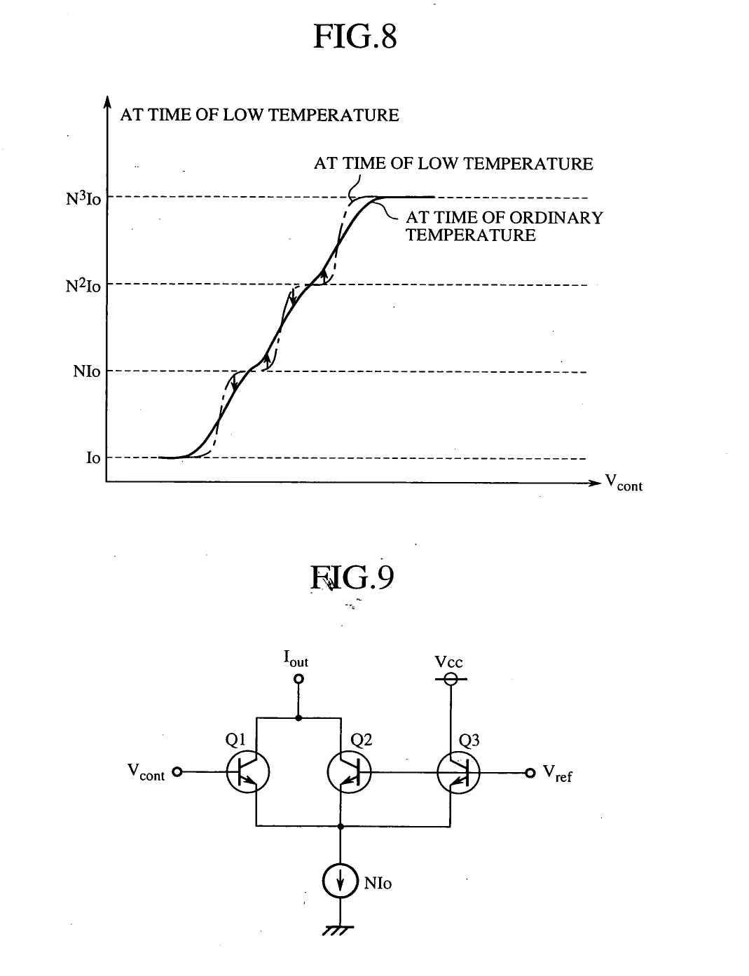

FIG. 7 is a characteristics figure showing the control voltage vs. output current characteristics of the variable gain amplifier at a high temperature, and FIG. 8 is a characteristics figure showing the control voltage vs. output current characteristics of the variable gain amplifier at a low temperature. When the plurality of element circuits are connected as mentioned above, since at a connecting point between any two adjacent element circuits their control voltage vs. output current characteristics curves are shifted in upward and downward directions due to the temperature dependence of the control voltage vs. output current characteristics of each of the two adjacent element circuits, respectively, the upward and downward shifted parts of the control voltage vs. output current characteristics curves can be compensated. Therefore, the temperature dependence of the control voltage vs. output current characteristics of the variable gain amplifier can be compensated.

### Embodiment 2

FIG. 9 is a circuit diagram showing the details of an example of an element circuit in accordance with embodiment 2 of the present invention, and shows the details of the element circuit 11 of FIG. 2. In the figure, reference symbol Q1 denotes a bipolar transistor (simply referred to as a transistor and also referred to as a first transistor from here on) having a base to which a control voltage Vcont is supplied, reference symbol Q2 denotes a transistor (i.e., a second transistor) having a base to which a reference voltage Vref is supplied, the transistor Q2 constituting a differential pair with the transistor Q1, and Q3 denotes a transistor (i.e., a third transistor) having a base to which the reference voltage Vref is supplied, the transistor Q3 constituting a current mirror circuit with the transistor Q2 and the ratio between the emitter areas of the transistors Q2 and Q3 being 1:N−1 when a constant rate at which an output current increases is N−1. The output current Iout is made to flow from a connecting point of the collectors of the transistors Q1 and Q2, and a power supply source Vcc is connected to the collector of the transistor Q3. Reference symbol NI₀ denotes a constant current source that makes a maximum output current flow through the element circuit and that is connected in common to the emitters of the transistors Q1 to Q3.

Next, the operation of the element circuit in accordance with embodiment 2 of the present invention will be explained.

In FIG. 9, when the control voltage Vcont is sufficiently small as compared with the reference voltage Vref, no current flows into the transistor Q1. In addition, since the combination of the transistors Q2 and Q3 is a current mirror circuit in which the ratio between their emitter areas is 1:N−1, a current having an amount of I₀ flows into the transistor Q2 and a current having an amount of (N−1)*I₀ flows into the transistor Q3. As a result, the current having the amount of I₀ flows as the output current Iout.

When the control voltage Vcont is sufficiently large as compared with the reference voltage Vref, a current having a maximum amount of N*I₀ flows into the transistor Q1, and no current flows into the transistors Q2 and Q3. As a result, the current having the maximum amount of N*I₀ flows as the output current Iout.

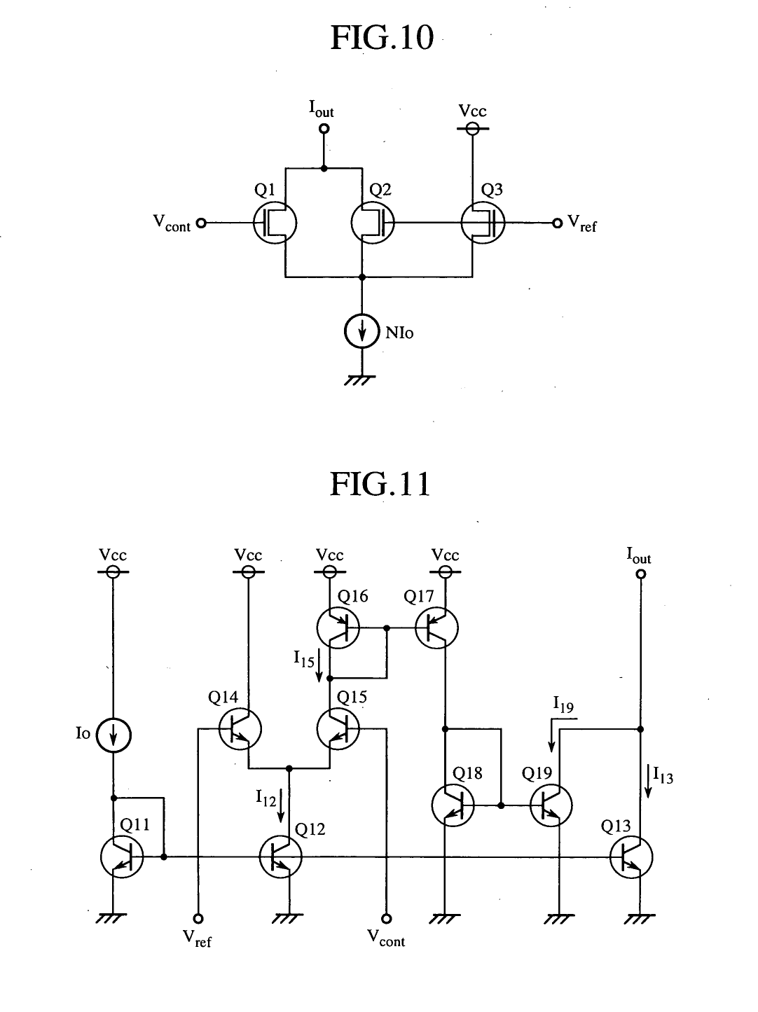

Thus, the element circuit 11 with a simple structure including bipolar transistors, as shown in FIG. 9, in which the amount of the output current Iout can be varied from I₀ to N*I₀ with a change in the control voltage Vcont can be manufactured. FIG. 10 is a circuit diagram showing the details of another example of the element circuit. The bipolar transistors Q1 to Q3 included in the element circuit 11 shown in FIG. 9 are replaced by MOSFETs Q1 to Q3, and the MOSFETs Q2 and Q3 are constructed so that the ratio of the gate widths of the MOSFETs Q2 and Q3 is 1:N−1. The structures of other components and the operation of the element circuit are the same as those shown in FIG. 9, and the element circuit 11 can be manufactured so as to have the structure of FIG. 10.

### Embodiment 3

FIG. 11 is a circuit diagram showing the details of an element circuit in accordance with embodiment 3 of the present invention, and shows the details of the element circuit 11 of FIG. 2. In the figure, reference symbol I₀ denotes a constant current source that generates a current having a constant amount of I₀, reference symbol Q11 denotes a bipolar transistor (simply referred to as a transistor on and also referred to as a first transistor from here) having a collector connected to the constant current source I₀, reference symbol Q12 denotes a transistor (i.e., a second transistor) which constitutes a current mirror circuit together with the transistor Q11, and reference symbol Q13 denotes a transistor (i.e., a third transistor) which constitutes a current mirror circuit together with the transistor Q11, the transistor Q13 having a collector connected to an output current terminal Iout.

Reference symbol Q14 denotes a transistor (i.e., a fourth transistor) to which a reference voltage Vref is supplied, the transistor Q14 having a collector connected to a power supply Vcc, and reference symbol Q15 denotes a transistor (i.e., a fifth transistor) to which a control voltage Vcont is supplied and which constitutes a differential pair together with the transistor Q14, the emitters of the transistors Q15 and Q14 being connected in common to the collector of the transistor Q12.

Reference symbol Q16 denotes a transistor having an emitter connected to the power supply Vcc and a collector connected to the collector of the transistor Q15, reference symbol Q17 denotes a transistor having an emitter connected to the power supply Vcc, the transistor Q17 constituting a current mirror circuit with the transistor Q16, reference symbol Q18 denotes a transistor having a collector connected to the collector of the transistor Q17, and reference symbol Q19 denotes a transistor having a collector connected to the current output terminal Iout, the transistor Q19 constituting a current mirror circuit with the transistor Q18. The transistors Q16 to Q19 constitute a transistor circuit network.

Next, the operation of the element circuit in accordance with embodiment 3 of the present invention will be explained.

In FIG. 11, the current mirror circuits constituted by the transistors Q11 to Q13 generate both a current having an amount corresponding to the rate of the emitter area of the transistor Q12 to that of the transistor Q11 and a current having an amount corresponding to the rate of the emitter area of the transistor Q13 to that of the transistor Q11, which flow through the transistors Q12 and Q13, respectively, from the constant current having an amount of I₀ flowing through the current source I₀.

A current which flows through the transistor Q12 flows into the transistor Q12 from the differential pair constituted by the transistors Q14 and Q15, and is separated into currents respectively flowing through the transistors Q14 and Q15 according to the potential difference between the reference voltage Vref and the control voltage Vcont.

When the control voltage Vcont is sufficiently small as compared with the reference voltage Vref, the current I₁₂ is all made to flow from the transistor Q14 to the transistor Q12 and therefore no current flows through the transistor Q15. In contrast, when the control voltage Vcont is sufficiently large as compared with the reference voltage Vref, the current I₁₂ is all made to flow from the transistor Q15 to the transistor Q12 and therefore I₁₅ becomes equal to I₁₂.

Both the current mirror circuit constituted by the transistors Q16 and Q17 and the current mirror circuit constituted by the transistors Q18 and Q19 generate a current 11 that flows through the transistor Q19 from the current I₁₅ that flows into the transistor Q15, the ratio between the currents I₁₉ and the current I₁₅ being associated with both the ratio between the emitter areas of the transistors Q16 and Q17 and the ratio between the emitter areas of the transistors Q18 and Q19.

When the current I₁₉ flowing through the transistor Q19 has a maximum value, the ratio between the emitter areas of the transistors Q12 and Q13, and the ratio among the transistors Q16 to Q19 included in the transistor circuit network are set so that the ratio of the current I₁₉ and the current I₁₃ which flows into the transistor Q13 becomes equal to N−1:1 (N−1 is a ratio at which an output current of the element circuit increases). In this case, when the control voltage Vcont is sufficiently small as compared with the reference voltage Vref, the current I₁₃=I₀ flows as the output current Iout, whereas when the control voltage Vcont is sufficiently large as compared with the reference voltage Vref, a current having an amount N*I₀ which is the sum of the current I₁=(N−1)*I₀ and the current I₁₃=I₀ flows as the output current Iout.

More concretely, the ratio between the emitter areas of the transistors Q12 and Q13 and the ratio among the emitter areas of the transistors Q16 to Q19 included in the transistor circuit network simply needs to be defined according to the following equation (2):
Q12*Q17*Q19/Q13*Q16*Q18=N−1 (2)

Thus, the element circuit 11 with a simple structure including bipolar transistors, as shown in FIG. 11, in which the output current Iout can be varied from I₀ to N*I₀ with a change in the control voltage Vcont can be manufactured.

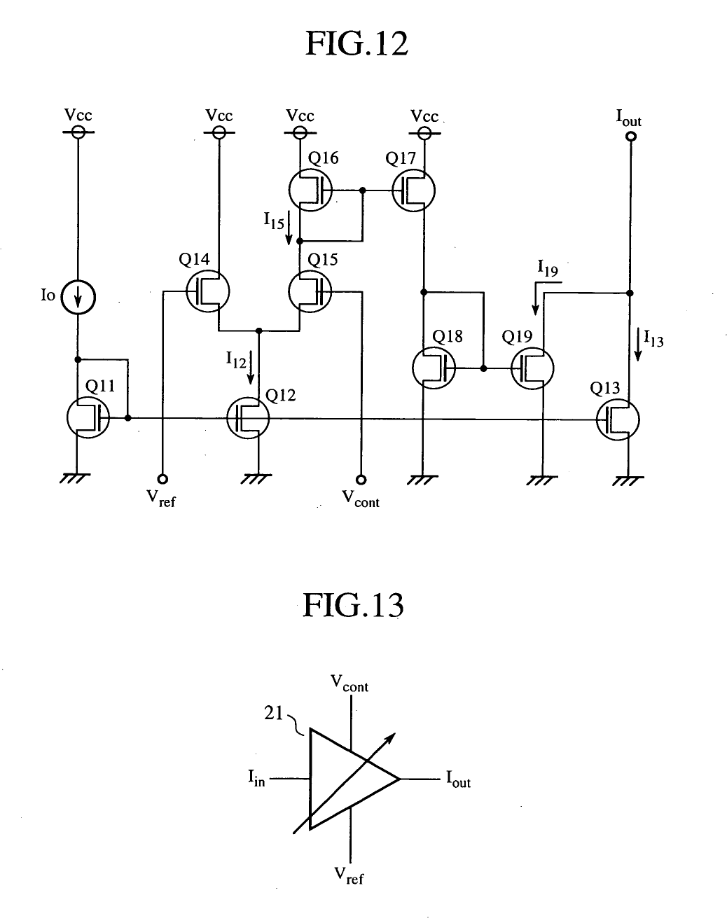

FIG. 12 is a circuit diagram showing the details of another example of the element circuit. The bipolar transistors Q11 to Q19 included in the element circuit 11 shown in FIG. 11 are replaced by MOSFETs Q11 to Q19, and the MOSFETs Q12 and Q13 and the MOSFETs Q16 and Q19 included in the transistor circuit network are constructed so that they have appropriate gate widths. The structures of other components and the operation of the element circuit are the same as those shown in FIG. 11, and the element circuit 11 can be manufactured so as to have the structure of FIG. 12.

### Embodiment 4

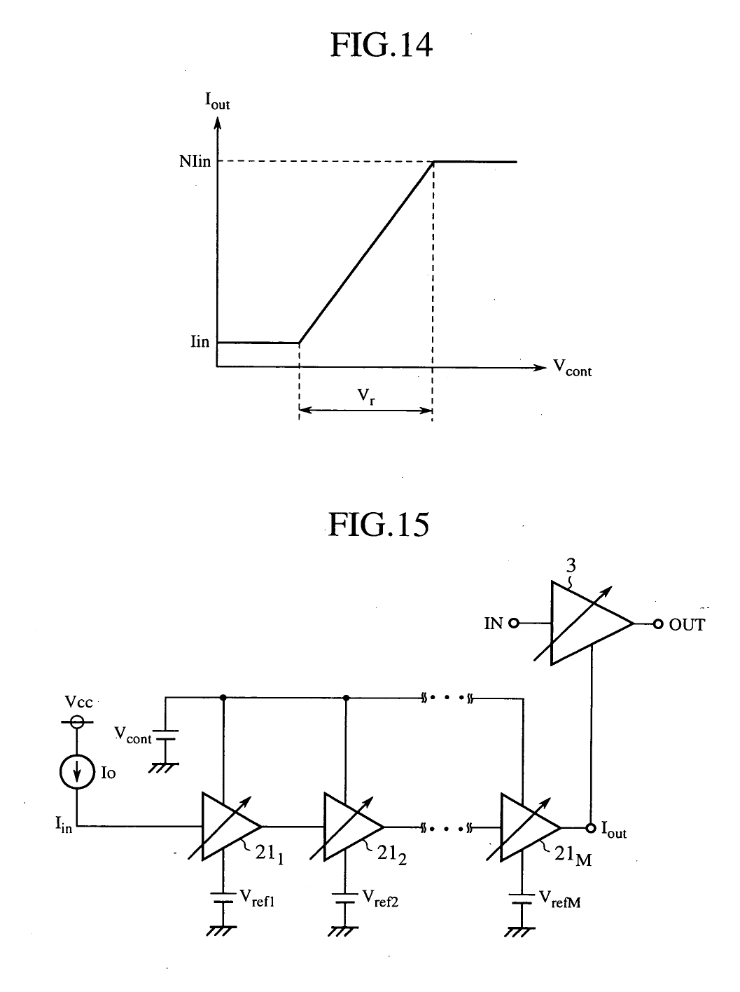

FIG. 13 is a block diagram showing an element circuit in accordance with embodiment 4 of the present invention. In the figure, reference numeral 21 denotes the element circuit. FIG. 14 is a characteristics figure showing control voltage vs. output current characteristics of the element circuit.

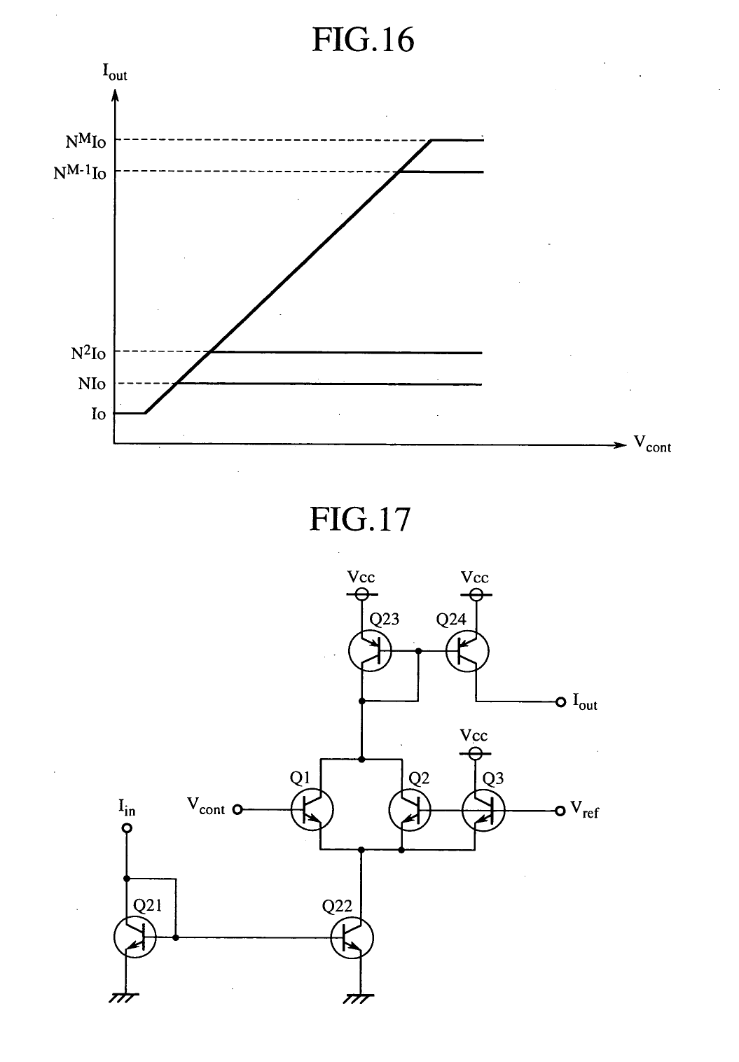

FIG. 15 is a block diagram showing a variable gain amplifier. In the figure, reference symbols 21₁ to 21_{M} denote M element circuits, respectively, and reference symbol I₀ denotes a constant current source that makes a current having a constant amount of I₀ flow into the variable gain amplifier. FIG. 16 is a characteristics figure showing control voltage vs. output current characteristics of the variable gain amplifier. The other structure of the variable gain amplifier is the same as that of the variable gain amplifier shown in FIG. 4.

Next, the operation of the variable gain amplifier in accordance with embodiment 4 of the present invention will be explained.

As shown in FIG. 13, the element circuit 21 has a signal input which is an input current Iin and a signal output which is an output current Iout. In the element circuit 21, a reference voltage Vref and a control voltage Vcont are disposed as power supplies.

The element circuit 21 has certain control voltage vs. output current characteristics in which the amount of the output current Iout varies from Iin to N*Iin with a predetermined change Vr in the control voltage Vcont, that is, the rate of increase in the output current is N−1 when the control voltage Vcont can be varied with-respect to the reference voltage Vref, as shown in FIG. 14.

As shown in FIG. 15, M element circuits 21, i.e., M element circuits 21₁ to 21_{M} are cascaded-connected in the variable gain amplifier, and the constant current I₀ is supplied, as the input current Iin, to the first-stage one of the plurality of element circuits. Furthermore, voltages that increase in steps of the predetermined voltage change Vr in the control voltage are respectively supplied to the plurality of element circuits 21₁ to 21_{M} as their reference voltages Vref1 to VrefM. That is, (VrefM)−(VrefM−1)=Vr. The variable control voltage Vcont is supplied in common to the plurality of element circuits 21₁ to 21_{M}.

The variable gain control of the amplifier 3 is carried out based on the output current Iout from the element circuit 21_{M} located at the last stage of the plurality of element circuits.

As a result, as shown in FIG. 16, the variable gain amplifier has control voltage vs. output current characteristics in which the amount of the output current Iout varies from I₀, via N*I₀, N²*I₀, . . . , to N^{M*I}₀ and is approximately expressed by an exponential function with respect to the voltage change Vr in the control voltage Vcont. When the gain of the amplifier 3 is expressed in a logarithm, the gain of the amplifier 3 can be linearly controlled with respect to the control voltage Vcont.

Thus, since the variable gain amplifier does not use exponential characteristics of transistors included in the variable gain amplifier, any change in the characteristics of the variable gain amplifier due to variations in manufacturing of the transistors can be suppressed.

By setting the number of element circuits included in the variable gain amplifier to an appropriate number and generating the plurality of reference voltages Vrefl to VrefM with a high degree of precision, the slope of the control voltage vs. output current characteristics curve can be hardly changed regardless of variations in manufacturing of the transistors in the whole of the variable gain amplifier, and any change in the characteristics of the variable gain amplifier can be suppressed.

When the plurality of element circuits are thus cascade-connected, since at a connecting point between any two adjacent element circuits their control voltage vs. output current characteristics curves are shifted in upward and downward directions due to the temperature dependence of the control voltage vs. output current characteristics of each of the two adjacent element circuits, respectively, the upward and downward shifted parts of the control voltage vs. output current characteristics curves can be compensated. Therefore, the temperature dependence can be compensated.

### Embodiment 5

FIG. 17 is a circuit diagram showing the details of an element circuit in accordance with embodiment 5 of the present invention, and shows the details of the element circuit 21 of FIG. 13. In the figure, reference symbol Q21 denotes a bipolar transistor (simply referred to as a transistor and also referred to as a fourth transistor) having a collector into which an input current Iin flows, and reference symbol Q22 denotes a transistor (i.e., a fifth transistor) having a collector connected in common to the emitters of transistors Q1 to Q3, the transistor Q22 constituting a current mirror circuit with the transistor Q21.

Reference symbol Q23 denotes a transistor having an emitter connected to a power supply Vcc and a collector connected in common to the collectors of the transistors Q1 and Q2, and reference symbol Q24 denotes a transistor having an emitter connected to the power supply Vcc, and a collector from which an output current Iout flows, the transistor Q24 constituting a current mirror circuit with the transistor Q23. The transistors Q23 and Q24 constitute an output current circuit. The other structure of the element circuit is the same as that of the element circuit shown in FIG. 9.

Next, the operation of the element circuit in accordance with embodiment 5 of the present invention will be explained.

In FIG. 17, the transistors Q21 and Q22 constitute a current mirror circuit, and the radio between their emitter areas is defined so that a current having an amount of N*Iin flows through the transistor Q22 with respect to the input current Iin.

When a control voltage Vcont is sufficiently small as compared with a reference voltage Vref, no current flows into the transistor Q1. In addition, since the transistors Q2 and Q3 constitute a current mirror circuit in which the ratio between their emitter areas is defined as 1:N−1, a current having an amount of Iin flows into the transistor Q2 and a current having an amount of (N−1)*Iin flows into the transistor Q3. As a result, a current having an amount of Iin flows through the transistor Q23, and a current having an amount of Iin flows through the transistor Q24 which constitutes a current mirror circuit together with the transistor Q23, as the output current Iout.

In contrast, when the control voltage Vcont is sufficiently large as compared with the reference voltage Vref, a current having a maximum amount of N*Iin flows into the transistor Q1, and no current flows into the transistors Q2 and Q3. As a result, a current having an amount of N*Iin flows through the transistor Q23, and a current having an amount of N*Iin flows through the transistor Q24 which constitutes a current mirror circuit together with the transistor Q23, as the output current Iout.

Thus, the element circuit 21 with a simple structure including bipolar transistors, as shown in FIG. 17, in which the amount of the output current Iout can be varied from Iin to N*Iin with a change in the control voltage Vcont can be manufactured.

The ratio between the emitter areas of the transistors Q21 and Q22 is defined as 1:N, as previously mentioned. As an alternative, the ratio among the emitter areas of the transistors Q21 to Q24 can be set so that Q22*Q24/Q21*Q23=N is satisfied.

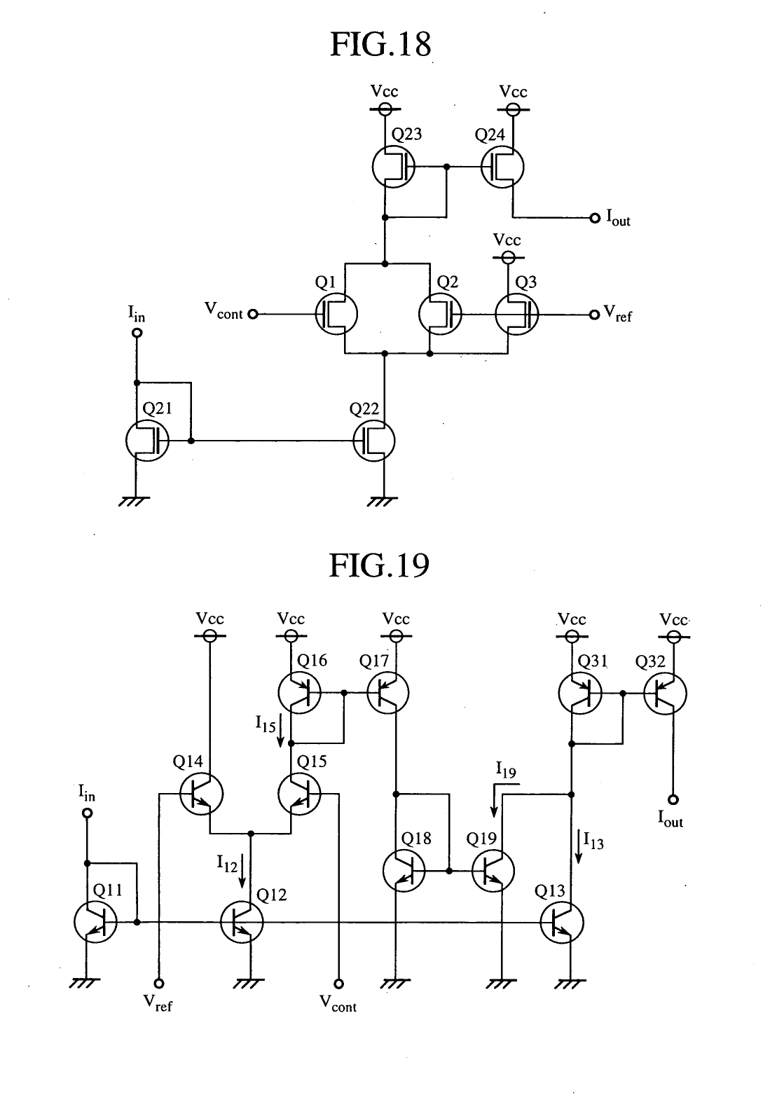

FIG. 18 is a circuit diagram showing the details-of another example of the element circuit. The bipolar transistors Q1 to Q3 and Q21 to Q24 included in the element circuit 21 shown in FIG. 17 are replaced by MOSFETs Q1 to Q3 and Q21 to Q24, and the MOSFETs Q2 and Q3 and the MOSFETs Q21 to Q24 are constructed so that the ratio between the gate widths of the MOSFETs Q2 and Q3 is defined as 1:N−1 and the ratio among the gate widths of the MOSFETs Q21 to Q24 is defined so that Q22*Q24/Q21*Q23=N is satisfied. The structures of other components and the operation of the element circuit are the same as those shown in FIG. 17, and the element circuit 21 can be manufactured so as to have the structure of FIG. 18.

### Embodiment 6

FIG. 19 is a circuit diagram showing the details of an element circuit in accordance with embodiment 6 of the present invention, and shows the details of an example of the element circuit 21 of FIG. 13. As shown in the figure, the element circuit is so constructed so that an input current Iin flows into the collector of a transistor Q11.

Reference symbol Q31 denotes a transistor having an emitter connected to a power supply Vcc and a collector connected in common to the collectors of transistors Q13 and Q19, and reference symbol Q32 denotes a transistor having an emitter connected to the power supply Vcc, and a collector connected to an output current terminal Iout, the transistor Q32 constituting a current mirror circuit with the transistor Q31. The transistors Q31 and Q32 constitute an output current circuit. The other structure of the element circuit is the same as that of the element circuit shown in FIG. 11.

Next, the operation of the element circuit in accordance with embodiment 6 of the present invention will be explained.

In FIG. 19, when the input current Iin flows into the transistor Q11, the transistors Q12 and Q13 make a current having an amount corresponding to the rate between the emitter 20 area of the transistor Q12 to that of the transistor Q11 and a current having an amount corresponding to the rate between the emitter area of the transistor Q13 to that of the transistor Q11 flow therethrough, respectively.

As a result, as previously mentioned in embodiment 3, when a control voltage Vcont is sufficiently small as compared with a reference voltage Vref, a current I₁₃=Iin flows through the transistor Q3, whereas when the control voltage Vcont is sufficiently large as compared with the reference voltage Vref, a current having an amount of N*Iin which is the sum of a current I₁₉=(N−1)*Iin and the current I₁₃=Iin flows into the transistor Q31.

Since the transistors Q31 and Q32 constitute a current mirror circuit, a current having the same amount as that of the current flowing through the transistor Q31 flows as an output current Iout.

Thus, the element circuit 21 with a simple structure including bipolar transistors, as shown in FIG. 19, in which the output current Iout can be varied from Iin to N*Iin with a change in the control voltage Vcont can be manufactured.

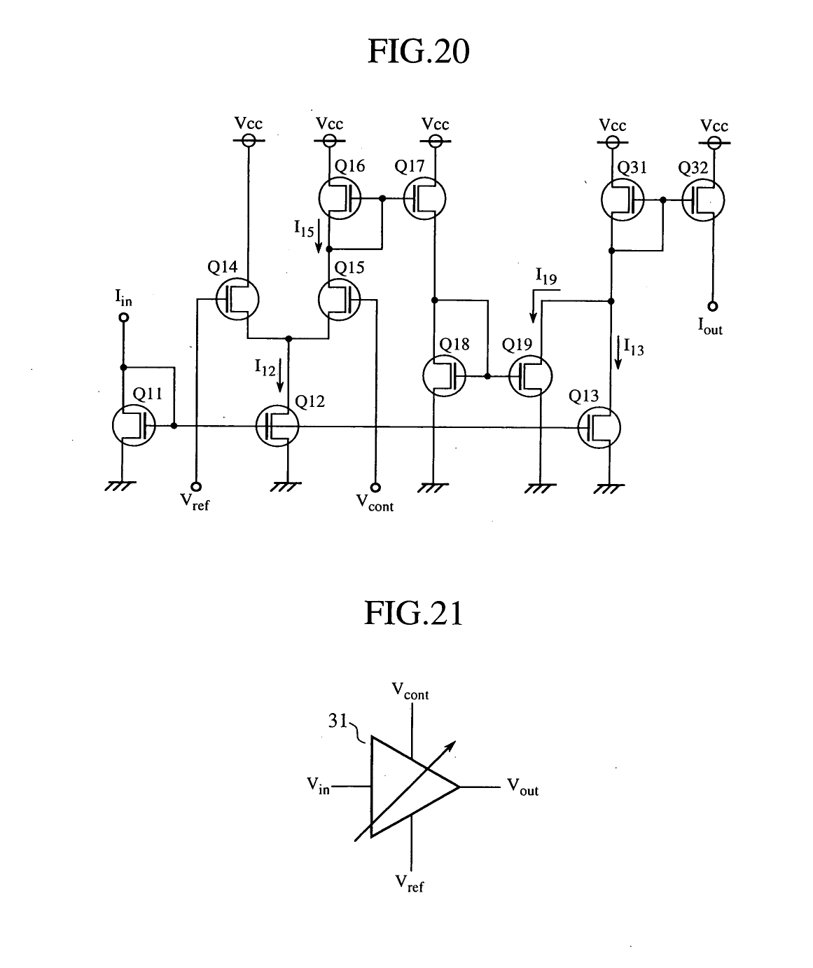

FIG. 20 is a circuit diagram showing the details of another example of the element circuit. The bipolar transistors Q11 to Q19 and Q31 and Q32 included in the element circuit 21 shown in FIG. 19 are replaced by MOSFETs Q11 to Q19 and Q31 and Q32, and the gate widths of the MOSFETs Q12 and Q13 are set to appropriate values and the gate widths of the MOSFETs Q16 to Q19 included in the transistor circuit network are set to appropriate values. The structures of other components and the operation of the element circuit are the same as those shown in FIG. 19, and the element circuit 21 can be manufactured so as to have the structure shown in FIG. 20.

### Embodiment 7

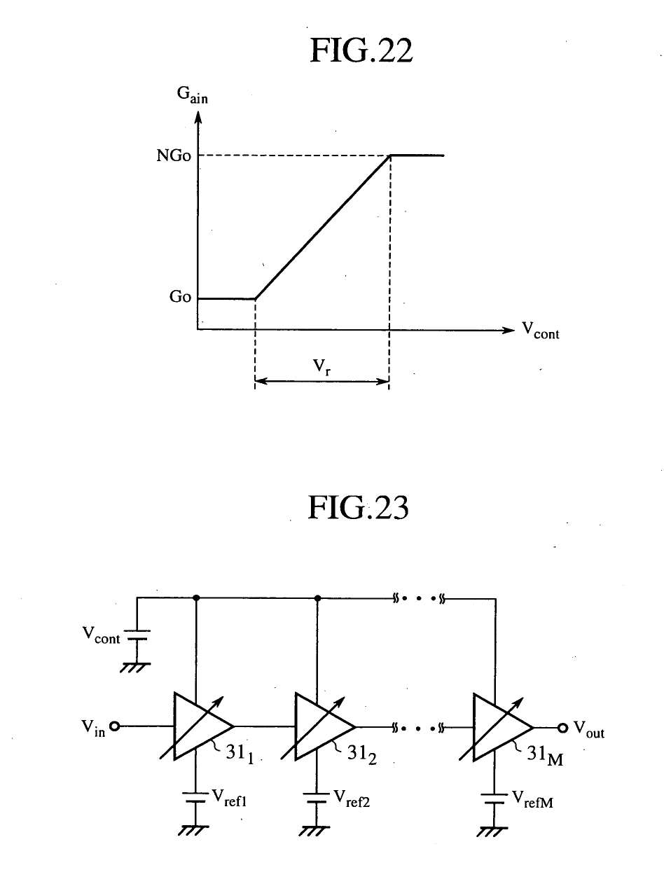

FIG. 21 is a block diagram showing an element circuit in accordance with embodiment 7 of the present invention. In the figure, reference numeral 31 denotes the element circuit. FIG. 22 is a figure showing control voltage vs. gain characteristics of the element circuit.

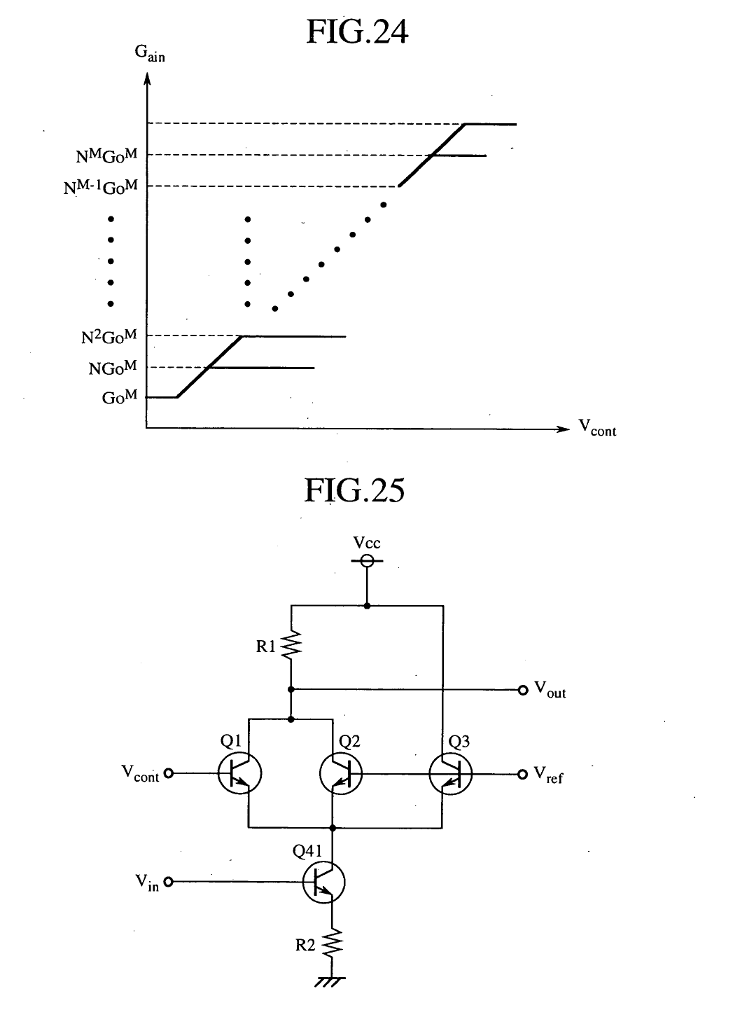

FIG. 23 is a block diagram showing a variable gain amplifier. In the figure, reference symbols 31₁ to 31_{M} denote M element circuits, respectively. FIG. 24 is a characteristics figure showing control voltage vs. gain characteristics of the variable gain amplifier.

Next, the operation of the variable gain amplifier in accordance with embodiment 7 of the present invention will be explained.

As shown in FIG. 21, the element circuit 31 has a signal input which is an input voltage Vin and a signal output which is an output voltage Vout. In the element circuit 31, a reference voltage Vref and a control voltage Vcont are disposed as power supplies.

The element circuit 31 has certain control voltage vs. gain characteristics in which its gain Gain varies from G₀ to N*G₀ with a predetermined change Vr in the control voltage Vcont, that is, the rate of increase in the gain is N−1 when the control voltage Vcont can be varied with respect to the reference voltage Vref, as shown in FIG. 22.

As shown in FIG. 23, M element circuits 31, i.e., the M element circuits 31₁ to 31_{M} are cascaded-connected in the variable gain amplifier, and an input voltage Vin is supplied to the first-stage one of the plurality of element circuits. Furthermore, voltages that increase in steps of the predetermined voltage change Vr in the control voltage are respectively supplied to the plurality of element circuits 311 to 31M as their reference voltages Vref1 to VrefM. That is, (VrefM)−(VrefM−1)=Vr. The variable control voltage Vcont is supplied in common to the plurality of element circuits 311 to 31M, and the output voltage Vout is generated by the element circuit 31M located at the last stage of the plurality of element circuits.

As a result, as shown in FIG. 24, the variable gain amplifier has control voltage vs. gain characteristics in which the gain Gain varies from G₀^{M}, via N*G₀^{M}, N²*G₀^{M}, . . . , to N^{M}*G₀^{M} and is approximately expressed by an exponential function with respect to the voltage change Vr in the control voltage Vcont. When the gain is expressed in a logarithm, the gain can be linearly controlled with respect to the control voltage Vcont.

Thus, since the variable gain amplifier does not use exponential characteristics of transistors included in the variable gain amplifier, any change in the characteristics of the variable gain amplifier due to variations in manufacturing of the transistors can be suppressed.

By setting the number of element circuits included in the variable gain amplifier to an appropriate number and generating the plurality of reference voltages Vrefl to-VrefM with a high degree of precision, the slope of the control voltage vs. gain characteristics curve can be hardly changed regardless of variations in manufacturing of the transistors in the whole of the variable gain amplifier, and any change in the characteristics of the variable gain amplifier can be suppressed.

When the plurality of element circuits are thus cascade-connected, since at a connecting point between any two adjacent element circuits their control voltage vs. gain characteristics curves are shifted in upward and downward directions due to the temperature dependence of the control voltage vs. gain characteristics of each of the two element circuits, respectively, the upward and downward shifted parts of the control voltage vs. gain characteristics curves can be compensated. Therefore, the temperature dependence can be compensated.

### Embodiment 8

FIG. 25 is a circuit diagram showing the details of an element circuit in accordance with embodiment 8 of the present invention, and shows the details of an example of the element circuit 31 of FIG. 21. In the figure, reference symbols R1 and R2 denote resistors, and reference symbol Q41 denotes a bipolar transistor (referred to as a transistor and also refereed to as a fourth transistor from here on) having a collector connected in common to the emitters of transistors Q1 to Q3, and an emitter connected to the resistor R2, an input voltage Vin being applied to the transistor Q41.

A power supply Vcc is connected to the collectors of the transistors Q1 and Q2 by way of the resistor R1, and is also connected directly to the collector of the transistor Q3. Furthermore, the element circuit is so constructed that an output voltage Vout is outputted from between the resistor R1 and the collectors of the transistors Q1 and Q2. The other structure of the element circuit is the same as that of the element circuit shown in FIG. 9.

Next, the operation of the element circuit in accordance with embodiment 8 of the present invention will be explained.

In FIG. 25, a current having an amount corresponding to the input voltage Vin flows into the transistor Q41. When a control voltage Vcont-is sufficiently small as compared with a reference voltage Vref, no current flows into the transistor Q1. In addition, since the transistors Q2 and Q3 constitute a current mirror circuit in which the ratio between the emitter areas of the transistors is defined as 1:N−1, a current having an amount of Iin flows into the transistor Q2 and a current having an amount of (N−1)*Iin flows into the transistor Q3. As a result, a current having an-amount of Iin flows through the resistor R1, and therefore a voltage of Iin*R1 is generated as the output voltage Vout.

When the control voltage Vcont is sufficiently large as compared with the reference voltage Vref, a current having a maximum amount of N*Iin flows into the transistor Q1, and no current flows into the transistors Q2 and Q3. As a result, a current having an amount of N*Iin flows through the resistor R1, and a voltage of N*Iin*R1 is generated as the output voltage Vout.

Thus, the element circuit 31 with a simple structure including bipolar transistors, as shown in FIG. 25, in which the output voltage Vout can be varied from Iin*R1 to N*Iin*R1 with a change in the control voltage Vcont, that is, the gain can be varied from G0 to N*G0, where Iin*R1 is defined as the gain G0, with a change in the control voltage Vcont can be manufactured.

### INDUSTRIAL APPLICABILITY

As mentioned above, the variable gain amplifier in accordance with the present invention is suitable for suppressing any change in the characteristics thereof due the temperature compensation of the characteristics and variations in manufacturing of transistors, and for carrying out a linear gain control operation on the control voltage.

1. A variable gain amplifier comprising: a plurality of element circuits each of which has two inputs which are a reference voltage and a control voltage which can vary with respect to the reference voltage, and each of which has an output current that increases at a constant rate with a predetermined change in the control voltage, voltages which increase in steps of the predetermined change in the control voltage being respectively supplied to said plurality of element circuits as their reference voltages and the variable control voltage being supplied to each of said plurality of element circuits;
multipliers for multiplying the output currents from said plurality of element circuits by one another; and
an amplifier for carrying out a variable gain amplification based on an output current obtained by said multipliers.

2. The variable gain amplifier according to claim 1, characterized in that each of said plurality of element circuits includes:
a first transistor to which the control voltage is supplied;
a second transistor to which the reference voltage is supplied and which constitutes a differential pair together with said first transistor; and
a third transistor to which the reference voltage is supplied and which constitutes a current mirror circuit together with said second transistor, a ratio between said second transistor and said third transistor in size being 1:N−1 when the constant rate at which the output current increases is N−1 (N is an arbitrary number larger than 1),
and characterized in that the output current is output in common from ends of said first and second transistors and a constant current source that outputs a maximum output current is connected in common to other ends of said first through third transistors.

3. The variable gain amplifier according to claim 1, characterized in that each of said plurality of element circuits includes:
a first transistor having an end connected to a constant current source;
a second transistor which constitutes a current mirror circuit together with said first transistor;
a third transistor which constitutes a current mirror circuit together with said first transistor, said third transistor having an end connected to an output current terminal;
a fourth transistor to which the reference voltage is supplied;
a fifth transistor to which the control voltage is supplied and which constitutes a differential pair together with said fourth transistor, ends of said fifth and fourth transistors being connected in common to an end of said second transistor; and
a transistor circuit network that diverts a part of a current from said output current terminal in proportion to a current flowing through said fifth transistor and that makes the part of the current pass therethrough without making it flow through said third transistor,
and characterized in that sizes of said second and third transistors and transistors included in said transistor circuit network are determined so that a ratio between the diverted part of the current and the current flowing through said third transistor is N−1:1 (N−1 is the constant rate at which the output current increases and N is an arbitrary number larger than 1) when the diverted part of the current has a maximum value.

4. A variable gain amplifier comprising:
a plurality of cascade-connected element circuits each of which has two inputs which are a reference voltage and a control voltage which can vary with respect to the reference voltage, and each of which has an output current that increases at a constant rate with a predetermined change in the control voltage, an input current being supplied to a first-stage one of said plurality of element circuits, voltages which increase in steps of the predetermined change in the control voltage being respectively supplied to said plurality of element circuits as their reference voltages, and the variable control voltage being supplied to each of said plurality of element circuits; and
an amplifier for carrying out a variable gain amplification based on an output current from said plurality of element circuits.

5. The variable gain amplifier according to claim 1, characterized in that each of said plurality of element circuits includes:
a first transistor to which the control voltage is supplied;
a second transistor to which the reference voltage is supplied and which constitutes a differential pair together with said first transistor;
a third transistor to which the reference voltage is supplied and which constitutes a current mirror circuit together with said second transistor, a ratio between said second transistor and said third transistor in size being 1:N−1 when the constant rate at which the output current increases is N−1 (N is an arbitrary number larger than 1);
a fourth transistor having an end into which an input current flows;
a fifth transistor that has an end connected in common to ends of said first through third transistors, and that constitutes a current mirror-circuit together with said fourth transistor; and
an output current circuit connected in common to other ends of said first and second transistors.

6. The variable gain amplifier according to claim 1, characterized in that each of said plurality of element circuits includes:
a first transistor having an end into which an input current flows;
a second transistor which constitutes a current mirror circuit together with said first transistor;
a third transistor which constitutes a current mirror circuit together with said first transistor, said third transistor having an end connected to an output current circuit;
a fourth transistor to which the reference voltage is supplied;
a fifth transistor to which the control voltage is supplied and which constitutes a differential pair together with said fourth transistor, ends of said fifth and fourth transistors being connected in common to an end of said second transistor; and
a transistor circuit network that diverts a part of a current from said output current circuit in proportion to a current flowing through said fifth transistor and that makes the part of the current pass therethrough without making it flow through said third transistor,
and characterized in that sizes of said second and third transistors and transistors included in said transistor circuit network are determined so that a ratio between the diverted part of the current and the current flowing through said third transistor is N−1:1 (N−1 is the constant rate at which the output current increases and N is an arbitrary number larger than 1) when the diverted part of the current has a maximum value.

7. A variable gain amplifier comprising: a plurality of cascade-connected element circuits each of which has two inputs which are a reference voltage and a control voltage which can vary with respect to the reference voltage, and each of which has a gain that increases at a constant rate with a predetermined change in the control voltage, an input voltage being supplied to a first-stage one of said plurality of element circuits, voltages which increase in steps of the predetermined change in the control voltage being respectively supplied to said plurality of element circuits as their reference voltages, the variable control voltage being supplied to each of said plurality of element circuits, and an output voltage being generated by a last-stage one of said plurality of element circuits.

8. The variable gain amplifier according to claim 7, characterized in that each of said plurality of element circuits includes:
a first transistor to which the control voltage is supplied;
a second transistor to which the reference voltage is supplied and which constitutes a differential pair together with said first transistor;
a third transistor to which the reference voltage is supplied and which constitutes a current mirror circuit together with said second transistor, a ratio between said second transistor and said third transistor in size being 1:N−1 when the constant rate at which the gain increases is N−1 (N is an arbitrary number larger than 1);
a fourth transistor to which an input voltage is supplied, said fourth transistor having an end connected in common to ends of said first through third transistors; and
a resistor connected between other ends of said first and second transistors and a power supply,
and characterized in that each of said plurality of element circuits generates an output voltage from between said resistor and the other ends of said first and second transistors.
